(19) United States
(12) Patent Application Publication
(10) Pub. No.: US 2013/0223017 A1
(43) Pub. Date: Aug. 29, 2013

(54) ELECTRONIC COMPONENT MODULE

(71) Applicant: Alps Electric Co., Ltd., (US)

(72) Inventors: Naoki Kitaura, Miyagi-ken (JP); Mamoru Gondo, Miyagi-ken (JP); Akinobu Adachi, Miyagi-ken (JP)

(73) Assignee: Alps Electric Co., Ltd., Tokyo (JP)

(21) Appl. No.: 13/860,333

(22) Filed: Apr. 10, 2013

Related U.S. Application Data
(63) Continuation of application No. PCT/JP2011/004505, filed on Aug. 9, 2011.

(30) Foreign Application Priority Data
Nov. 4, 2010 (JP) 2010-247136

(51) Int. Cl. H05K 7/06

(52) U.S. Cl. CPC H05K 7/06
USPC 361/728

(57) ABSTRACT

An electronic component module includes a rectangular insulating substrate; lands that are arranged on a substrate surface thereof; electronic components that are connected to the lands using solder, and are mounted on the substrate surface; a solder resist protective layer that protects a wiring pattern by covering the substrate surface, and that is raised from the substrate surface toward the electronic components; a non-resist forming region that is not subjected to the solder resist and that exposes the substrate surface; and a sealing resin that seals the electronic components on the substrate surface. The non-resist forming region is formed in such a way as to communicate one side which partitions the substrate surface with another side which is separated from the one side, which partitions the substrate surface, through bottoms of component rear surfaces of the electronic components on the substrate surface.

### CLAIM OF PRIORITY

This application is a Continuation of International Application No. PCT/JP2011/004505 filed on Aug. 9, 2011, which claims benefit of Japanese Patent Application No. 2010-247136 filed on Nov. 4, 2010. The entire contents of each application noted above are hereby incorporated by reference in its entirety.

### BACKGROUND

1. Field of the Disclosure

The present disclosure relates to an electronic component module which covers electronic components mounted on an insulating substrate using sealing resin.

2. Description of the Related Art

Various kinds of lands and wiring patterns are formed on a substrate surface of this kind of insulating substrate. Electronic components are mounted on the substrate surface through wireless bonding using, for example, a flip-chip method, that is, the electronic components are mounted on the substrate surface using reflow after solder bumps are provided on bonding pads of component rear surfaces and the positions of the solder bumps and the lands are aligned.

Subsequently, for example, if a liquid underfill agent fills into gaps between the component rear surfaces and the substrate surface and the underfill agent hardens, it is possible to strengthen connections made by the solder bumps, and thus the connection reliability between the electronic components and the insulating substrate improves.

Here, a technology which fills sealing resin into gaps between the component rear surfaces and the substrate surface instead of the underfill agent has been proposed (for example, refer to Japanese Unexamined Patent Application Publication No. 2004-103998, Japanese Unexamined Patent Application Publication No. 2006-173493, and Japanese Unexamined Patent Application Publication No. 2006-339524).

More specifically, if an insulating substrate on which electronic components are mounted is set in a mold and pressurized sealing resin (which includes a filler) is poured into the mold, it is possible to cover the peripheries of the electronic components, more specifically, component surfaces in addition to the component rear surfaces at the same time (molded underfill structure). Therefore, it is possible to accomplish a smaller and thinner electronic component module and a low manufacturing cost, compared to a structure in which electronic components are covered by a metal cover.

The reason is that a space which is used to avoid interference with the metal cover and each of the electronic components becomes a dead space, in addition, when the underfill agent fills into the gaps, it is difficult to have each of the electronic components close to each other, further, it is necessary to have the bottoms of the component rear surfaces raised, and thus the dead space becomes large. However, in the molded underfill structure, it is possible to omit each of these spaces and the metal cover is not necessary.

However, a solder resist protective layer is provided on the above substrate surface, and covers and protects the wiring pattern which is formed in the substrate surface. The reason for this is that, if melted solder flows through the wiring pattern (a solder flow phenomenon), a solder bridge which electrically connects the lands with the wiring pattern is generated, and thus a short circuit failure of the wiring pattern is caused.

Besides, since the protective layer is raised from the substrate surface toward the electronic components, the bottoms of the component rear surfaces become low. In particular, in the above-described molded underfill structure, that is, in a structure in which a thin electronic component module is accomplished by causing the bottoms of the component rear surfaces to be low, it is difficult for the resin which is poured into the gaps to flow.

Further, here, air (void) remains in the resin which is filled in the bottoms of the component rear surfaces, and thus there is a problem in that it is difficult to maintain connection reliability.

The reason for this is that solder bumps are remelted when reflow connection is performed on the electronic component module and a motherboard, the air which remains in the resin expands when the solder bumps are remelted, and if stress operates on the resin in the periphery of the solder bumps, crack may be generated in the resin. In addition, if a void which spans between solder bumps is present, a phenomenon is generated in which solder is short-circuited when the solder is remelted.

In this case, it may be taken into consideration of the application of a groove which is disclosed in the above-described related art, in particular, Japanese Unexamined Patent Application Publication No. 2004-103998, more specifically, a groove which is obtained by removing a part of the protective layer and which supplements the fluidity by guiding the resin.

However, the periphery of the groove disclosed in the technology is closed by the protective layer, and the resin should go through the protective layer and then reach the groove. That is, it is easy for the air to still remain in the boundary division of the protective layer and the bottom surface of the groove, and it is easy for the void to generate again.

In contrast, although it is taken into consideration to use resin which includes filler having a narrow diameter or to use low-viscosity resin, this reduces the advantage of the molded underfill structure accomplishing the low-manufacturing cost.

As discussed above, a problem with regard to the great increase in the fluidity of resin still remains in the related art.

### SUMMARY

An electronic component module according to a first aspect of the invention includes: a rectangular insulating substrate; lands that are arranged on a substrate surface of the insulating substrate; electronic components that are connected to the lands using solder, and are mounted on the substrate surface; a solder resist protective layer that protects a wiring pattern by covering the substrate surface, and that is raised from the substrate surface toward the electronic components; a non-resist forming region that is not subjected to the solder resist and that exposes the substrate surface; and a sealing resin that seals the electronic components on the substrate surface. The non-resist forming region is formed in such a way as to communicate one side, which partitions the substrate surface, with another side which is separated from the one side, which partitions the substrate surface, through the bottoms of the component rear surfaces of the electronic components on the substrate surface.

### BRIEF DESCRIPTION OF THE DRAWINGS

FIG. 1 is a perspective view illustrating an appearance of a tuner according to an embodiment;

FIG. 2 is a cross sectional view of the tuner taken along a line II-II of FIG. 1;

FIG. 3 is a planar view illustrating an insulating substrate in FIG. 1 and a view illustrating a state in which electronic components are mounted thereon;

FIG. 4 is a planar view illustrating the insulating substrate in FIG. 1 and a view illustrating lands and a wiring pattern;

FIG. 5 is a planar view illustrating the insulating substrate in FIG. 1 and a view illustrating a protective film;

FIG. 6 is a view illustrating a flow direction of resin in FIG. 5;

FIG. 7 is a flowchart illustrating a process to manufacture the turner in FIG. 1;

FIG. 8 is a view illustrating the manufacture process in FIG. 6;

FIG. 9 is a view illustrating the manufacture process in FIG. 6;

FIG. 10 is a view illustrating the manufacture process in FIG. 6; and

FIG. 11 is a view illustrating the manufacture process in FIG. 6.

### DESCRIPTION OF THE EXEMPLARY EMBODIMENTS

Hereinafter, exemplary embodiments of the present invention will be described with reference to the accompanying drawings.

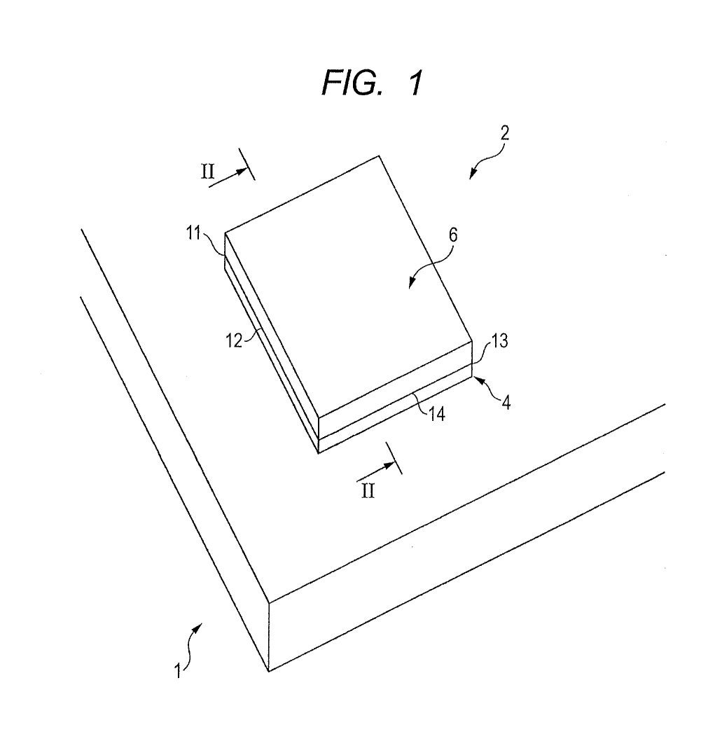

FIG. 1 is a perspective view illustrating an appearance of a television tuner (an electronic component module) 2 according to an embodiment, and the tuner 2 is received in the housing of a mobile device, for example, a mobile phone, together with a motherboard 1, and is capable of receiving a terrestrial digital broadcasting signal.

The tuner 2 includes a rectangular insulating substrate 4 in a planar view.

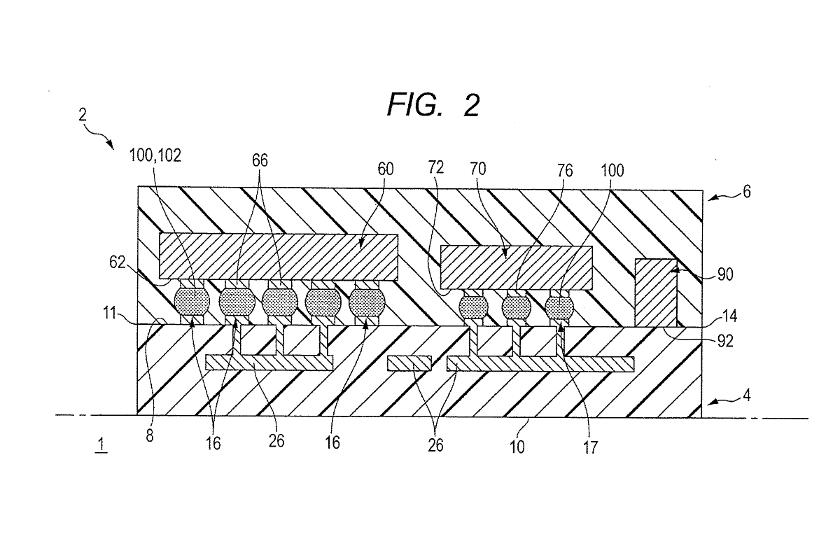

The insulating substrate 4 includes a substrate surface 8 and a substrate rear surface 10 which face each other in the thickness direction of the insulating substrate 4 and have the same shape (see FIG. 2). The insulating substrate 4 is fixed to the motherboard 1 through terminals (not shown) which are formed in the substrate rear surface 10.

The edge of the substrate surface 8 is partitioned using a front side (one side) 11, lateral sides 12 and 13, and a rear side (the other side) 14 (see FIG. 1). The front side 11 and the rear side 14 are formed to have lengths which are shorter than those of the lateral sides 12 and 13. In FIG. 1, both the right and left ends of each of the front side 11 and the rear side 14 cross the left lateral side 12 and the right lateral sides 13, respectively.

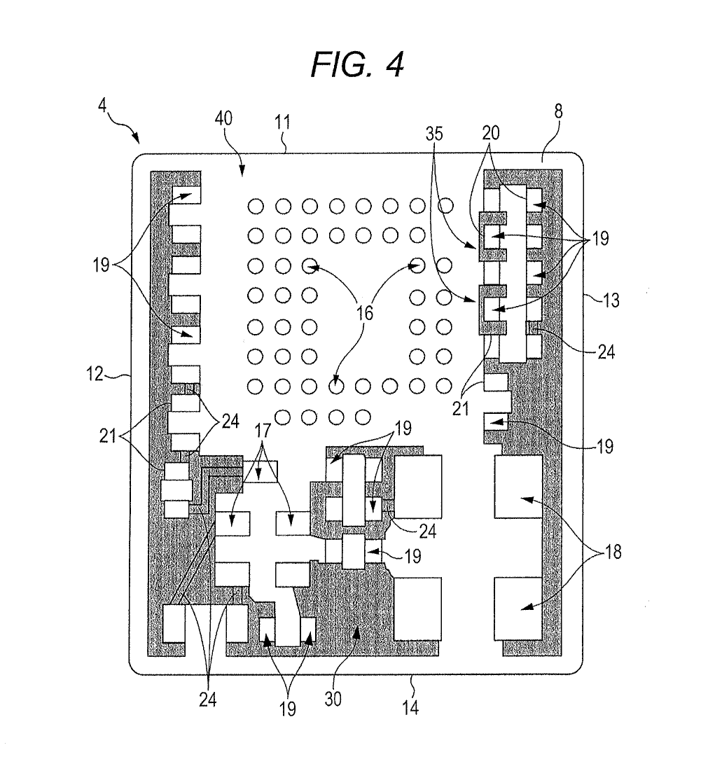

In addition, as shown in FIG. 2, the insulating substrate 4 includes an inner wiring pattern 26 on an inside layer which is on a side lower than the substrate surface 8. The wiring pattern 26 is formed of, for example, copper foil, and is electrically conducted with lands 16 and 17, which are arranged on the substrate surface 8, and the above-described terminals of the substrate rear surface 10 via through holes. In addition, the arrangement of the lands 16 and 17 will be additionally described with reference to FIG. 4.

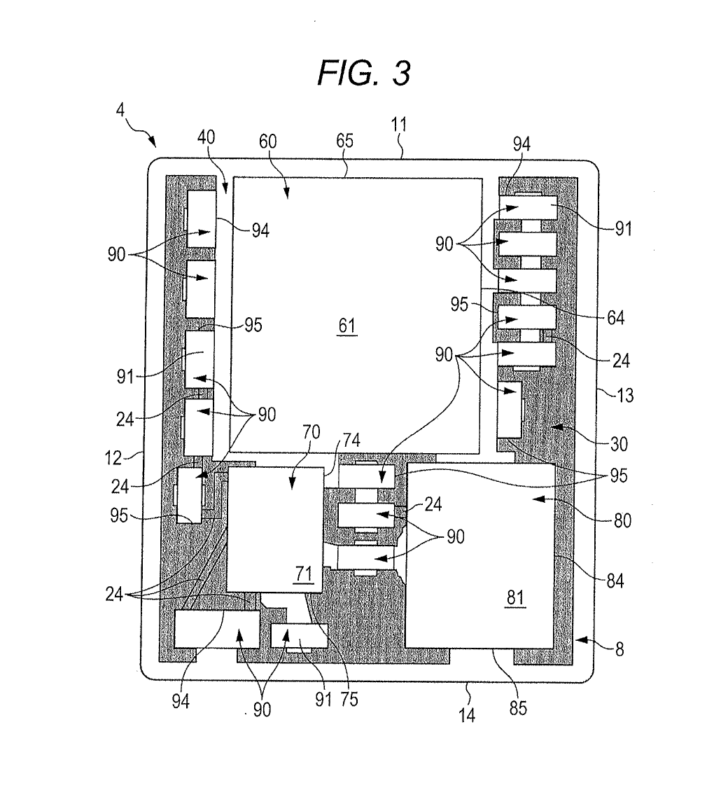

A plurality of electronic components 60, 70, 80, and 90, which configure the tuner 2, are mounted on the substrate surface 8 according to the embodiment (see FIG. 3). In addition, in FIG. 3 and FIGS. 4 to 6 below, the sealing resin 6 shown in FIGS. 1 and 2 is omitted for convenience of explanation of the structure.

More specifically, first, an Integrated Circuit (IC) 60 is the largest electronic component of the mounted electronic components, that is, the electronic component which has the largest area when viewed from the tangential direction of the substrate surface 8, and has functions corresponding to, for example, a phase synchronization circuit, an oscillating circuit, and a mixed circuit.

The IC 60 is provided near the front side 11 of the substrate surface 8 in FIG. 3, and includes a rectangular component surface 61 in a planar view. In addition, a component rear surface 62, shown in FIG. 2, forms the same shape as the component surface 61.

The component surface 61 and the component rear surface 62 are partitioned using long sides 64 and short sides 65 which cross each other. As shown in FIG. 3, the long sides 64 are arranged along the lateral sides 12 and 13, the short sides 65 which are on the inner side in the drawing is arranged to be close to front side 11.

Subsequently, a notch filter 70 is a middle-sized electronic component which is smaller than the IC 60, and has functions of passing a television receiving wave and cutting a transmitting wave of a mobile phone.

The notch filter 70 is provided between the IC 60 and the rear side 14 in FIG. 3, and has a rectangular component surface 71 in a planar view. In addition, a component rear surface 72, shown in FIG. 2, forms the same shape as the component surface 71.

The component surface 71 and the component rear surface 72 are further partitioned using long sides 74 and short sides 75 which cross each other. The long sides 74 are arranged along the lateral sides 12 and 13, and the short sides 75 which are on the inner side in FIG. 3 are arranged to be close to the short sides 65 of the IC 60.

Continuously, a crystal oscillator 80 is a middle-sized electronic component which is smaller than the IC 60 but is larger than the notch filter 70, and has a function corresponding to a local oscillator.

Like the notch filter 70, the crystal oscillator 80 is provided between the IC 60 and the rear side 14 in FIG. 3, and includes a rectangular component surface 81 in a planar view. In addition, the component rear surface thereof has the same shape as the component surface 81 although not shown in the cross-sectional view in FIG. 2.

The component surface 81 and the component rear surface are partitioned using long sides 84 and short sides 85 which cross each other, the long sides 84 are arranged along the lateral sides 12 and 13, and the short sides 85 which are on the inner side when viewed in FIG. 3 is arranged to be close to the short side 65 of the IC 60. On the other hand, the front short sides 85 in the drawing is arranged to be close to the rear side 14.

In addition, chip components 90 are small-sized electronic components which are smaller than the notch filter 70. Each of the chip components 90 has a function of adjusting operations of the IC 60, the notch filter 70, and the crystal oscillator 80.

In detail, each chip component 90 further has a rectangular component surface 91 in a planar view. In addition, a component rear surface 92 shown in FIG. 2 further has the same shape as a component surface 91.

The component surface 91 and the component rear surface 92 are partitioned using long sides 94 and short sides 95 which cross each other. According to the embodiment, total 16 chip components 90 are mounted on the substrate surface 8 (see FIG. 3), and the directions of the long sides 94 and the short sides 95 differ depending on the position of the chip component 90.

More specifically, first, four chip components 90 each having a longitudinal direction along the lateral side 12 are arranged on the left side of the IC 60 in FIG. 3.

That is, the long sides 94 are arranged in the direction which is parallel to the long sides 64 of the IC 60, and the short sides 95 are arranged in the direction which is perpendicular to the long sides 64, respectively. In the embodiment, two chip components 90, which are on the front side in FIG. 3, of the four chip components 90 are connected to surface wiring pattern 24 which is provided in the substrate surface 8. The wiring pattern 24 is formed by, for example, copper foil.

In addition, six chip components 90 are arranged on the right side of the IC 60. The five chip components 90 thereof have longitudinal directions which cross the lateral side 13.

In other words, the long sides 94 are arranged in the direction which is perpendicular to the long side 64 of the IC 60, and the short sides 95 are arranged in the direction which is parallel to the long side 64, respectively. In the embodiment, two chip components 90, which are on the front side in FIG. 3, of the five chip components 90 are connected to the surface wiring pattern 24 which is provided in the substrate surface 8.

Besides, a remaining single chip component 90 which is on the right side of the IC 60 has a longitudinal direction arranged along the lateral side 13. The chip component 90 has long sides 94 arranged in the direction which is parallel to the long side 64 of the IC 60, and has short sides 95 arranged in the direction which is perpendicular to the long side 64, respectively.

Further, a single chip component 90 is arranged in a position which is close to the front side of the IC 60 in FIG. 3, and the chip component 90 has a longitudinal direction which crosses the lateral side 13. That is, long sides 94 are arranged in the direction which is parallel to the short side 65 of the IC 60, and a short side 95 is arranged in the direction which is perpendicular to the short side 65, respectively.

In addition, total eleven chip components 90 which are provided in the periphery of the IC 60 are appropriately connected to the IC 60 via the inner wiring pattern 26 shown in FIG. 2.

Subsequently, a single chip component 90 is arranged on the left side of the notch filter 70 in FIG. 3. The chip component 90 has a longitudinal direction arranged along the lateral side 12, has long sides 94 arranged in the direction which is parallel to the long sides 74 of the notch filter 70, and has short sides 95 arranged in the direction which is perpendicular to the long sides 74, respectively.

In the embodiment, the chip component 90 is connected to the above-described chip component 90 which is provided on the left sides of the notch filter 70 and the IC 60 using the surface wiring pattern 24 which is provided in the substrate surface 8.

In addition, two large and small chip components 90 are arranged on the front side of the notch filter 70 in FIG. 3, and both the longitudinal directions thereof cross the lateral side 12.

That is, long sides 94 are arranged in the direction which is parallel to the short sides 75 of the notch filter 70, and short sides 95 are arranged in the direction which is perpendicular to the short sides 75, respectively. In the embodiment, the large chip component 90 on the left side of the two chip components 90 is connected to the notch filter 70 via the surface wiring pattern 24 which is provided in the substrate surface 8. Besides, the small chip component 90 on the right side id connected to the notch filter 70 via the inner wiring pattern 26 shown in FIG. 2.

Further, three chip components 90, including a chip component 90 which is connected to the above-described IC 60, are arranged on the right side of the notch filter 70. All the chip components 90 have long sides 94 arranged in the direction which is perpendicular to the long sides 74 of the notch filter 70, respectively. A chip component 90 which is on the most front side in FIG. 3 is connected to the notch filter 70 via the inner wiring pattern 26.

Besides, the central chip component 90 of the three chip components 90 is connected to the crystal oscillator 80 via the surface wiring pattern 24 which is provided in the substrate surface 8.

As described above, in the embodiment, the large-sized and middle-sized electronic components which correspond to the IC 60, the notch filter 70, and the crystal oscillator 80 have the long sides 64, 74, and 84 which are arranged in parallel to the lateral sides 12 and 13. In addition, the short sides 65 of the IC 60 are close to the short sides 75 and 85 of the notch filter 70 and the crystal oscillator 80. No chip component 90 is arranged between the short side 65 and the short sides 75 and 85.

In addition, the IC 60, the notch filter 70, and the crystal oscillator 80 are mounted on the lands 16, 17, and 18 of the substrate surface 8 using solder bumps 100 shown in FIG. 2, and the chip components 90 are mounted on the lands 19 on the substrate surface 8, respectively, (see FIG. 4) using, for example, solder pastes (not shown).

More specifically, as shown in FIG. 4 in which each of the electronic components is dismounted from FIG. 3, first, the lands 16 are formed in circular shapes in a planar view, and the plurality of lands 16 are arranged in the projection range of the component rear surface 62 of the IC 60.

Further, the IC 60 is mounted on the substrate surface 8 using reflow after the solder bumps 100 are provided on the bonding pads 66 of the component rear surface 62 and the positions of the solder bumps 100 and the lands 16 are aligned. The IC 60 is appropriately connected to the inner wiring pattern 26 shown in FIG. 2.

Here, as shown in FIG. 2, reserve solders 102 are provided in the lands 16 according to embodiment.

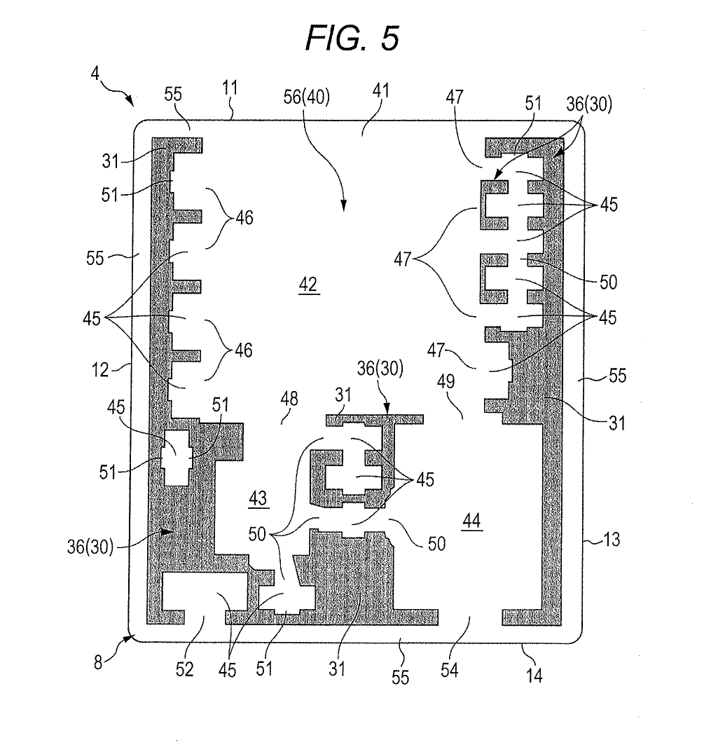

Each of the reserve solders 102 is formed in advance on each of the lands 16 in a thickness of approximately 30 μm (1 μm=1×10⁻⁶ m), and has a large drum shape in conjunction with the solder bump 100 in the case of reflow. As a result, it is possible to cause a wide gap (gap) 56 from the component rear surface 62 to the substrate surface 8, which will be described later with reference to FIG. 5, to be higher than a wide gap 56 which is formed using only the solder bumps 100.

Besides, returning to FIG. 4, all the lands 17 to 19 are formed in rectangular forms in a planar view. First, five lands 17 are arranged in the projection range of the component rear surface 72 of the notch filter 70, more specifically, in positions which correspond to the corners of the component rear surface 72 and a center of the long side 74 and the short side 75.

Subsequently, four lands 18 are arranged in the projection range of the component rear surface of the crystal oscillator 80, more specifically, in positions which correspond to the corners of the component rear surface.

Further, in the notch filter 70 and the crystal oscillator 80, the solder bumps 100 are further provided on the bonding pads 76 of the component rear surface 72. After the positions of the solder bumps 100 and the lands 17 and 18 are respectively aligned, the solder bumps 100 and the lands 17 and 18 are mounted on the substrate surface 8 using reflow. Therefore, the notch filter 70 and the crystal oscillator 80 are appropriately connected to the surface wiring pattern 24 and the inner wiring pattern 26.

Subsequently, two lands 19 are arranged in the projection range of the component rear surface 92 of each of the chip components 90, in detail, positions which correspond to both end portions of each of the component rear surfaces 92 in the longitudinal direction. The long sides 20 are extended in the direction which is perpendicular to the longitudinal direction of the chip component 90, and the short sides 21 are extended in the direction which is parallel to the longitudinal direction of the chip component 90, respectively. When the chip components 90 are mounted on the substrate surface 8 using solder paste, the chip components 90 are appropriately connected to the surface wiring pattern 24 or the inner wiring pattern 26.

A television signal which is received by the above-described tuner 2 is input to the mixed circuit of the IC 60 via the phase synchronization circuit, the oscillating circuit of the IC 60 and, further, the notch filter 70. In addition, a local oscillation signal is input to the mixed circuit from the crystal oscillator 80, and the mixed circuit mixes the television signal with the local oscillation signal, and converts into an intermediate frequency signal.

Subsequently, unnecessary frequency components are removed from the intermediate frequency signal, and then an attenuated intermediate frequency signal is detected and amplified. Therefore, it is possible to output an image signal or a sound signal, which is optimal for a television signal process, from the terminals of the substrate rear surface 10 toward the motherboard 1.

However, a solder resist layer (a protective layer) 30 is subjected to the substrate surface 8 (see FIGS. 3 and 4).

As shown in FIG. 5 in which the circular-shaped lands 16 in a planar view, the rectangular lands 17 to 19 in a planar view, and the surface wiring pattern 24 is omitted from FIG. 4, in addition to FIGS. 3 and 4, the solder resist layer 30 is a location which is solid-filed using a darker color than that of the periphery.

More specifically, the solder resist layer 30 according to the embodiment protects the surface wiring pattern 24 (see FIG. 4), and prevents the lands 17 to 19 from being electrically connected with the wiring pattern 24 due to molten solder.

That is, the solder resist layer 30 covers the surface wiring pattern 24, surrounds the rectangular lands 17 to 19 in a planar view, and is arranged in the vicinities of the lateral sides 12 and 13 and the rear side 14 on a large scale. More specifically, the location which is solid-filed using darker color in FIGS. 4 and 5 extended from the vicinity of the intersections between the front side 11 and the lateral sides 12 and 13 to the vicinity of the intersections between the rear side 14 and the lateral sides 12 and 13. In addition, the location is present from the front side of the installation position of the IC 60 to the rear side 14.

Besides, since the chip components 90 are arranged to be, in particular, close to each other, the solder resist layer 30 which is interposed between the lands 19 is connected to an adjacent solder resist layer 30.

For example, when attention is given to five chip components 90 which are arranged in the vicinity of the right-side lateral side 13, the longitudinal directions thereof cross the lateral side 13 (see FIG. 3). Further, an approximately U-shaped solder resist layer 30 which has an opening toward the lateral side 13, is provided on the land 19, which is near to the IC 60, of the lands 19,19 of each of the second and fourth chip components 90 from the inside in FIG. 4 (see FIGS. 4 and 5).

The pillar section of the U-shaped solder resist layer 30 covers between the respective short sides 21 of the adjacent lands 19. Besides, the bottom section of the U-shaped solder resist layer 30 is connected to the pillar section along a long side 20 which is near to the IC 60. Therefore, it is possible to increase the area of the solder resist layer 30, compared to a case in which the solder resist layer 30 includes only the pillar section.

In addition, the solder resist layer 30 according to the embodiment does not surround the circular-shaped lands 16 in a planar view. The reason for this is that the lands 16 are electrically conducted with the inner wiring pattern 26, and thus the lands 16 are not electrically conducted with the surface wiring pattern 24. In addition, as described above, the reserve solders 102 are provided on the lands 16 according to the embodiment, and thus the wide gap 56 from the component rear surface 62 to the substrate surface 8 becomes higher.

As above, since the solder resist layer 30 protects the surface wiring pattern 24, the protective layer surface 31 thereof is raised (approximately 20 μm) toward the IC 60, the notch filter 70, the crystal oscillator 80, and the chip components 90.

In other words, the narrow gap (gap) 36 in FIG. 5 which corresponds to a space from each of the component rear surfaces 62, 72, and 92 to the protective layer surface 31 is lower than the wide gap 56 which corresponds to the space from the component rear surfaces 62, 72, and 92 to the substrate surface 8.

In contrast, a non-resist forming region 40 which configures the wide gap 56 is provided in the entire region excepting the solder resist layer 30 of the substrate surface 8.

More specifically, as shown in FIG. 5, the non-resist forming region 40 is a location which is displayed using a fainter color than that of the solder resist layer 30, and a location in which the substrate surface 8 is exposed until the sealing resin 6 is filled.

Further, the non-resist forming region 40 is formed under each of the component rear surfaces of the IC 60, the notch filter 70, the crystal oscillator 80, and the chip components 90 from the front side 11, that is, formed in such a way as to communicate to the rear side 14 through the projection ranges such as the component rear surfaces 62, 72, and 92. The wide gap 56 which is formed by the non-resist forming regions 40 is higher than the narrow gap 36 which is formed by the solder resist layer 30 by a degree of approximately 20 μm.

More specifically, the non-resist forming region 40 according to the embodiment includes five types of regions. (see FIG. 5).

First, a resin inlet (a substrate edge opening in an inlet side) 41 which is close to the front side 11 is provided in the surface substrate 8. The resin inlet 41 forms the inlet of the supplied sealing resin 6, is provided between the solder resist layers 30, 30 which are solid-filled using dark color in the vicinity of the intersection of the front side 11 and the lateral sides 12 and 13 in FIG. 5, is formed using the wide gap 56 which is the same as the front side 11, and is connected to the front side 11.

In addition, a resin outlet (a substrate edge opening in an outlet side) 54 which is close to the rear side 14 is provided in the surface substrate 8. The resin outlet 54 forms the outlet of the supplied sealing resin 6, and is provided between the solder resist layers 30, 30 which are solid-filled using the dark color in the vicinity of the intersection of the rear side 14 and the lateral side 13 and on the front side of the installation position of the crystal oscillator 80 in FIG. 5. The resin outlet 54 is also formed using the wide gap 56 which is the same as the rear side 14, and is connected to the rear side 14.

That is, the resin outlet 54 according to the embodiment is provided on an opposite side to the resin inlet 41 while the surface substrate 8 is interposed therebetween. In addition, as understood with reference to FIG. 5, the opening area of the resin inlet 41 is formed to be larger than the opening area of the resin outlet 54.

In other words, it is understood that an end surface which includes the short side 65 of the large-sized IC 60 is close to the resin inlet 41, and the end surface which includes the short side 85 of the middle-sized crystal oscillator 80 is closer to the resin outlet 54 than the resin inlet 41.

Subsequently, non-resist forming sections 42, 43, 44, and 45 are provided on the inner periphery side of the solder resist layers 30, 30 which extend along the lateral sides 12 and 13 between the front side 11 and the rear side 14.

The non-resist forming sections 42, 43, 44, and 45 correspond to the wide gap 56 which is positioned at the bottoms of the component rear surfaces of the respective electronic components.

The non-resist forming section 42 corresponds to the bottom of the component rear surface of the large-sized IC 60, the non-resist forming section 43 corresponds to the bottom of the component rear surface of the middle-sized notch filter 70, the non-resist forming section 44 corresponds to the bottom of the component rear surface of the middle-sized crystal oscillator 80, and the non-resist forming sections 45 correspond to the bottoms of the component rear surfaces of the small-sized chip components 90, respectively.

In addition, the non-resist forming section 42 communicates with the resin inlet 41 on the back side in FIG. 5, and the non-resist forming section 44 communicates with the resin outlet 54 on the front side in the drawing.

Therefore, it is understood that, in the large-sized IC 60, the middle-sized notch filter 70 and the crystal oscillator 80, all the long sides 64, 74, and 84 are particularly arranged in a direction in which the non-resist forming sections 42 and 44 are formed, that is, arranged along from the resin inlet 41 to the resin outlet 54 which is on the opposite side of the resin inlet 41.

However, according to the embodiment, only the wide gap 56 which is at the bottom of the large-sized IC 60 is higher than the wide gaps 56 at the bottoms of the notch filter 70 and the crystal oscillator 80 by the reserve solder 102 having a thickness of approximately 30 μm.

Therefore, although the wide gaps 56 on the sides of the notch filter 70 and the crystal oscillator 80 are higher than the narrow gap 36 by approximately 20 μm, the wide gap 56 on the side of the IC 60 is higher than the narrow gap 36 by approximately 50 μm.

That is, it is understood that, even in a case of the same wide gaps 56, the IC 60 which has the higher wide gap 56 is close to the resin inlet 41, and the notch filter 70 and the crystal oscillator 80, which have wide gaps 56 having normal heights, are closer to the resin outlet 54 than the resin inlet 41.

Subsequently, each of the non-resist forming sections 42, 43, 44, and 45 communicates with each other using inside relay openings (relay openings) 46, 47, 48, 49, and 50.

More specifically, the inside relay openings 46, 47, 48, 49, and 50 are regions which do not correspond to the bottoms of the component rear surfaces of the respective electronic components. However, first, the inside relay openings 46 cause the left side of the non-resist forming section 42 to be increased toward the lateral side 12 in FIG. 5, and connect the non-resist forming section 42 with four non-resist forming sections 45 which are positioned in the vicinity of the lateral side 12.

In addition, the inside relay openings 47 cause the right side of the non-resist forming section 42 to be increased toward the lateral side 13 in FIG. 5, and connect the non-resist forming section 42 with four non-resist forming sections 45 which are positioned in the vicinity of the lateral side 13 excepting the bottom of the U-shaped solder resist layer 30.

Further, the inside relay opening 48 connects the front side of the non-resist forming section 42 with the back side of the non-resist forming section 43 in FIG. 5. Besides, the inside relay opening 49 connects the front side of the non-resist forming section 42 with the back side of the non-resist forming section 44 in the drawing.

Further, in addition, the inside relay openings 50 respectively connect the central sections of the five non-resist forming sections 45 which are positioned in the vicinity of the lateral side 13 along the lateral side 13, and connect the non-resist forming section 43 with a single non-resist forming section 45 on the front side.

Further, the inside relay openings 50 respectively connect the non-resist forming section 43 with two non-resist forming sections 45 which are on the right side of the non-resist forming section 43, and connect the non-resist forming section 45, which is on the front side of the non-resist forming section 43, of the two non-resist forming sections 45 with the non-resist forming section 44.

In addition, inflow inlets 51 are formed in the respective non-resist forming sections 45. The inflow inlets 51 cause the sealing resin 6 to be further easily guided to the non-resist forming sections 45, and are appropriately installed in the central sections of the long sides of the respective non-resist forming sections 45, which do not communicate with the inside relay openings 46, the inside relay openings 47, and the inside relay openings 50, and causes the regions of the non-resist forming sections 45 to broaden.

As described above, the wide gap 56, which is formed by the non-resist forming region 40 displayed using the fainter color than that of the solder resist layer 30, is successive over a wide range on the inner periphery side of the solder resist layers 30, 30 which are extended along the lateral sides 12 and 13 between the front side 11 and the rear side 14.

Besides, the non-resist forming region 40 according to the embodiment includes non-edge forming sections 55 which cause the resin inlet 41 to communicate with the resin outlet 54 on the outer periphery sides of the solder resist layers 30, 30 which extend along the lateral sides 12 and 13.

The non-edge forming sections 55 are formed along the front side 11, the lateral sides 12 and 13, and the rear side 14, respectively, and provide the wide gap 56 on the outer periphery side of the solder resist layer 30. In addition, the non-edge forming section 55, which is positioned on the rear side 14, of the non-edge forming sections 55, and a non-resist forming section 45 which corresponds to the large chip component 90 are connected by an outside relay opening 52.

That is, the non-resist forming region 40 according to the embodiment includes the outside relay opening 52 which introduces the sealing resin 6 from the outside of the substrate surface 8 to the non-resist forming sections 45 which are continuous to not only the inner periphery sides of solder resist layers 30,30 extending along the lateral sides 12 and 13 but also, for example, the rear side 14, and which are not continuous to the non-resist forming section 43 and the inside relay opening 50.

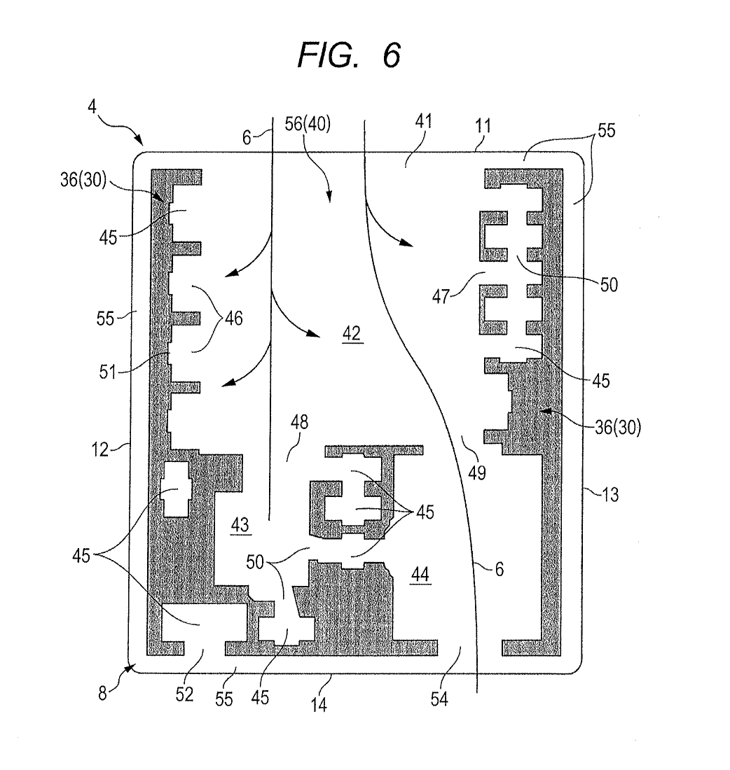

Further, as shown using arrows in FIG. 6, the sealing resin 6 which is collected in the vicinity of the front side 11 is introduced from the large resin inlet 41 to the substrate surface 8, and broadens into the non-resist forming section 42. The mainstream of the sealing resin 6 reaches the non-resist forming section 43 through the inside relay opening 48 and reaches the non-resist forming section 44 through the inside relay opening 49.

At the same time, the sealing resin 6 reaches the non-resist forming sections 45 from the inside relay openings 46 and 47, and, in addition, reaches adjacent non-resist forming sections 45 through the inside relay opening 50.

In addition, the sealing resin 6 which runs on solder resist layer 30 reaches the non-resist forming sections 45 from the inflow inlet 51 or the like.

The sealing resin 6 which reached the non-resist forming sections 43 reaches circumferential non-resist forming sections 45, and reaches the non-resist forming section 44 through the inside relay opening 50. Thereafter, the sealing resin 6 from the non-resist forming sections 43 joins with the sealing resin 6 which reached the non-resist forming section 44 through the inside relay opening 49, is drawn from the resin outlet 54, and is collected in the vicinity of the rear side 14.

Besides, the sealing resin 6 which is collected in the vicinity of the front side 11 and the sealing resin 6 which run on the solder resist layer 30 broaden into the outer periphery side of the solder resist layers 30, that is, the non-edge forming section 55. The sealing resin 6 which broadens into the non-edge forming section 55 reaches the non-resist forming section 45 which corresponds to the large chip component 90 through the outside relay opening 52, joins with the sealing resin 6 which reached the non-resist forming section 43, or is collected in the vicinity of the rear side 14.

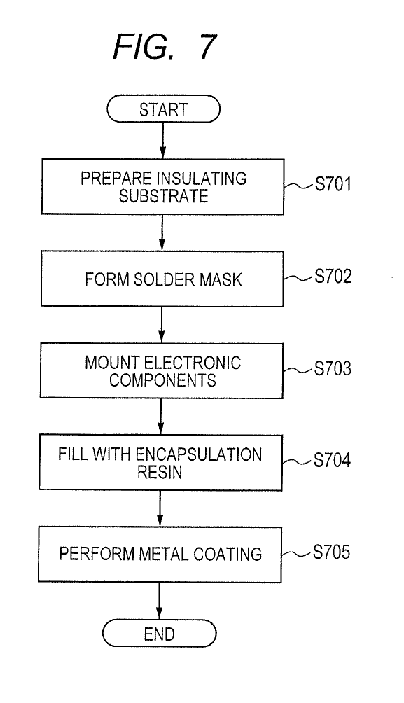

The above-described tuner 2 is manufactured using a process shown in FIG. 7.

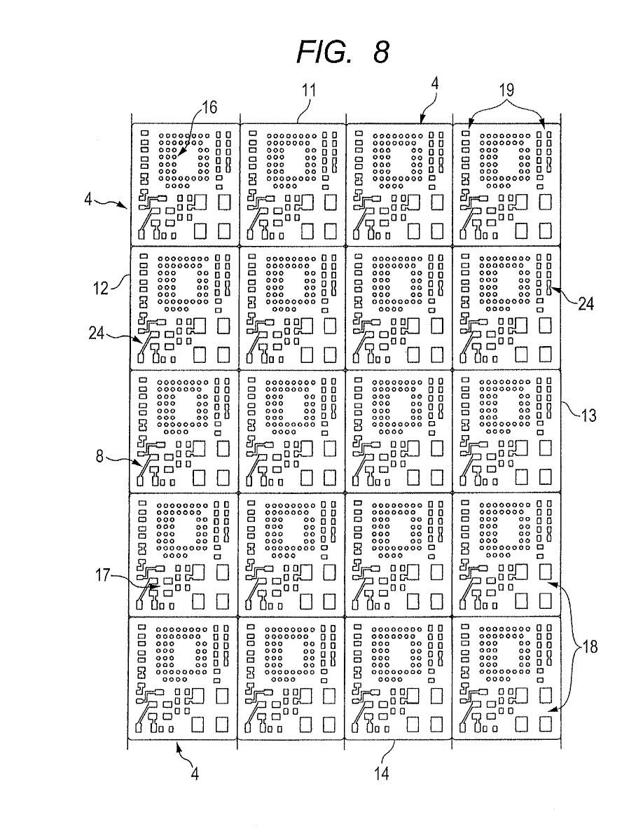

First, in step S701 in the drawing, the insulating substrates 4 are prepared. In detail, as shown in FIG. 8, for example, an assembly of the insulating substrates 4, which are aligned in four rows in the vertical direction, is prepared. In the assembly, the lateral sides 12 and 13, which are adjacent on the right and left, of the respective insulating substrates 4 are connected while some gaps is provided therebetween. In addition, the front sides 11 and the rear sides 14, which are adjacent to the front and rear, of the respective insulating substrates 4 are connected while some gap is provided therebetween.

The lands 16 to 19 and the surface wiring pattern 24 are provided in the substrate surface 8 of each of the insulating substrates 4. In addition, the inner wiring pattern 26 is provided in the inside layer of each of the insulating substrates 4.

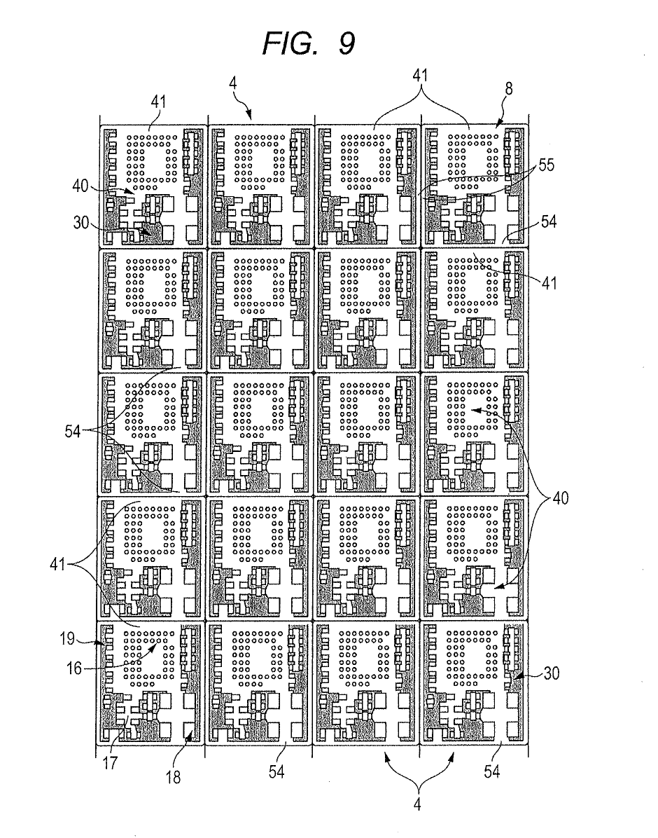

Subsequently, in step S702 in FIG. 7, the solder resist layer 30 is provided. More specifically, as shown in FIG. 9, the epoxy solder resist layer 30 is formed in the peripheries of the lands 17, 18, and 19 using, for example, screen printing in a region excepting the non-resist forming region 40 of each of the substrate surfaces 8, and covers over the surface wiring pattern 24.

Therefore, when each of the substrate surfaces 8, which are adjacent to front and back, is viewed, the resin outlet 54 of a precedent substrate surface 8 is connected to the resin inlet 41 of a subsequent substrate surface 8 while the front side 11 is interposed therebetween. In addition, each of the substrate surfaces 8, which are adjacent on the right and left, is viewed, it is understood that the non-edge forming section 55 which is positioned on the lateral side 13 of the left substrate surface 8 is continuous to the non-edge forming section 55 which is positioned on the lateral side 12 of the right substrate surface 8.

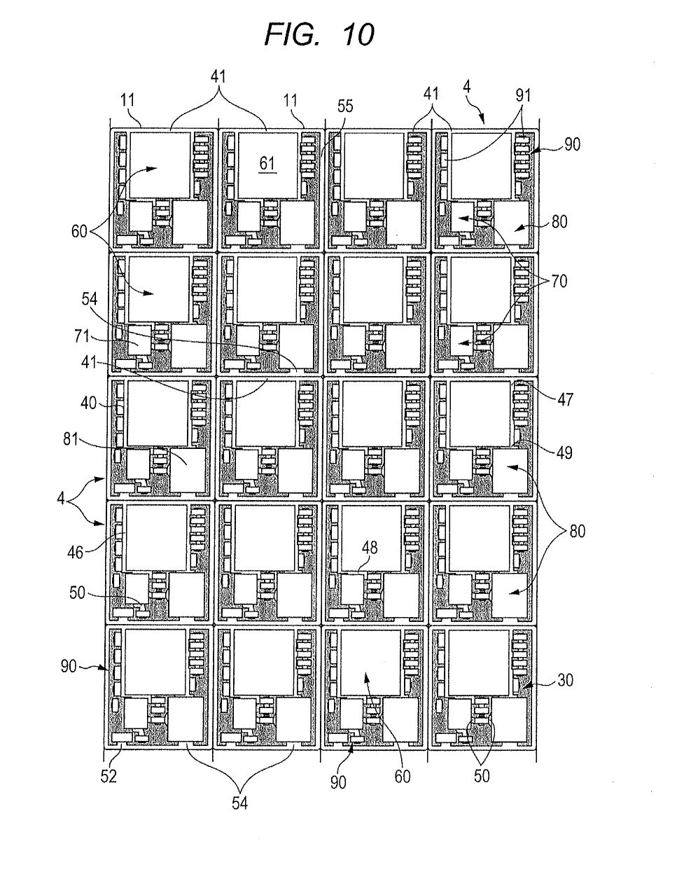

Subsequently, when the process proceeds to step S703, the IC 60, the notch filter 70, the crystal oscillator 80, and each of the electronic components of the chip components 90 are mounted on the lands 16 to 19 of each of the substrate surfaces 8 using the solder bumps 100, the non-resist forming sections 42, 43, 44, and 45 are hidden by the respective electronic components in each of the insulating surfaces 4, and thus the inside relay openings 46, 47, 48, 49, and 50, the resin inlet 41, the resin outlet 54, the outside relay opening 52, and the non-edge forming section 55 which are in the periphery of the electronic components are viewed, as shown in FIG. 10.

Further, in step S704, the sealing resin 6 is filled. More specifically, after the assembly of the insulating substrates 4 in FIG. 10 is set on a mold (not shown), if the sealing resin 6 which includes a filler to which predetermined pressure is applied is funneled into the mold, the sealing resin 6 is supplied from each front side 11 on the most back side in FIG. 10, and is filled into the wide gap 56 and the narrow gap 36 while forming the appearance of the tuner 2 by covering the component surfaces 61, 71, 81, and 91 of the respective electronic components.

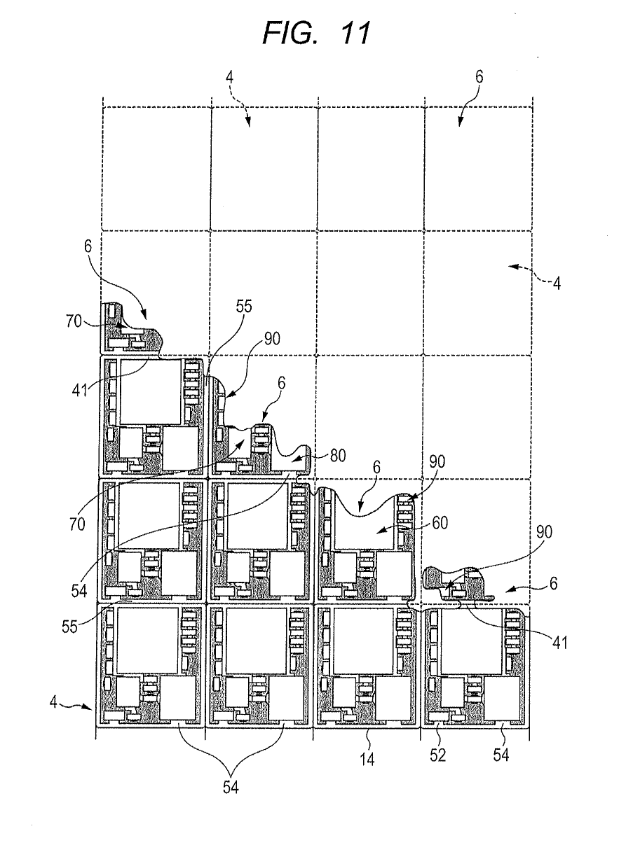

More specifically, the sealing resin 6 flows from the back side toward the front side in FIG. 11, enters the non-resist forming section 42 from the resin inlet 41 of each of the substrate surfaces 8, buries the non-resist forming sections 43, 44, and 45 and reaches the resin outlet 54 through the inside relay openings 46, 47, 48, 49, and 50. After the sealing resin 6 is accumulated in the vicinity of the rear side 14, that is, the front side 11 of a subsequent substrate surface 8, the sealing resin 6 enters the non-resist forming section 42 of the substrate surface 8.

In addition, the sealing resin 6 reaches the non-resist forming sections 45 which correspond to the large-sized chip components 90 from the non-edge forming section 55 through the outside relay opening 52. Further, if the assembly of the insulating substrates 4 is completely filled with the sealing resin 6, the assembly of the insulating substrates 4 is taken out from the mold, metal coating is performed on, for example, the ceiling plane of the sealing resin 6 in step S705, and a series of routine ends. Thereafter, division is performed on the assembly for each insulating substrate 4, and the substrates 4 which are obtained through the division are respectively mounted on the motherboard 1.

As described above, according to the embodiment, the lands 16 to 19 are arranged in the rectangular substrate surface 8, all of the large-sized IC 60, the middle-sized notch filter 70 and crystal oscillator 80, and each of the electronic components of the small-sized chip components 90 are connected to the lands 16 to 19 using solder and are mounted in the substrate surface 8.

Further, if the periphery of each of the electronic components is covered by the sealing resin 6 instead of the metal cover, it is possible to collectively seal the solder (molded underfill structure). Therefore, it is possible to configure a small-sized, thinned, and low-cost tuner 2, compared to the case in which the periphery of each of the electronic components is shielded using the metal cover.

Here, the solder resist layer 30 and the non-resist forming region 40 are provided on the substrate surface 8.

More specifically, the solder resist layer 30 protects the surface wiring pattern 24 which is formed in the substrate surface 8, and covers the substrate surface 8. In contrast, a region, to which the solder resist layer 30 is not subjected and which exposes the substrate surface 8 until the sealing resin 6 is filled, is the non-resist forming region 40.

That is, the solder resist layer 30 is raised from the substrate surface 8 toward the electronic components 60, 70, 80, and 90, the protective layer surface 31 and the substrate surface 8 have a difference in height, and the wide gap 56 from the component rear surfaces 62, 72, and 92 to the substrate surface 8 is higher than the narrow gap 36 from the component rear surfaces 62, 72, and 92 to the protective layer surface 31.

Further, the non-resist forming region 40 according to the embodiment is formed to communicate from the front side 11 which partitions the substrate surface 8 to the rear side 14 which is different from the front side 11 through the bottoms of the component rear surfaces 62, 72, and 92 in the substrate surface 8. Therefore, the sealing resin 6 can rapidly fill the wide gap 56 which exposes the substrate surface 8, and can immediately seal the solder.

As above, since the non-resist forming region 40 which exposes the substrate surface 8 truly increase the fluidity of the resin between the front side 11 and the rear side 14, it is possible to complete the sealing operation of the sealing resin 6 during a short time. In addition, since a filler having a thin diameter is not necessary for the sealing resin 6, it is possible to acquire a molded underfill structure using an inexpensive resin, and thus the lowering of a manufacturing cost is not inhibited.

However, if the non-resist forming region 40 can lower resin-flow resistance, the solder is completely filled with resin, and thus it is difficult for a void to be generated.

Therefore, even though the solder is remelted when reflow connection is performed on the tuner 2 and the motherboard 1, it is possible to prevent the resin 6 from cracking. As a result, the connection reliability between each of the electronic components 60, 70, 80, and 90 and the insulating substrate 4 is improved, and, further, it becomes easy to adjust the amount of solder which is necessary to form the solder bumps 100.

In addition, since the sealing resin 6 is directly adhered to the substrate surface 8 in the non-resist forming region 40, this fact contributes to the improvement of the connection reliability between each of the electronic components 60, 70, 80, and 90 and the insulating substrate 4.

Further, if the plurality of electronic components 60, 70, 80, and 90 are mounted on the substrate surface 8, the bottom of each of the component rear surfaces 62, 72, and 92 increases by the number of electronic components 60, 70, 80, and 90 in the substrate surface 8, and thus resin-flow resistance increases.

However, the non-resist forming region 40 between the front side 11 and the rear side 14 does not correspond to the non-resist forming sections 42 to 45 which make the wide gap 56 and the bottom of each of the component rear surfaces 62, 72, and 92, but includes the inside relay openings 46 to 50 which communicate with each of the non-resist forming sections 42 to 45, and thus it is possible to install the wide gap 56 which is higher than the above-described narrow gap 36 throughout the wide range of the substrate surface 8.

Therefore, even though the plurality of electronic components 60, 70, 80, and 90 are mounted on the substrate surface 8, the fluidity of the resin which flows into the bottom of each of the component rear surfaces 62, 72, and 92 of the substrate surface 8 is not impeded.

Besides, the large-sized chip component 90 is provided on the front side of the notch filter 70 in FIG. 3. Although the non-resist forming section 45 thereof is at the bottom of the component rear surface of the chip component 90, the non-resist forming section 45 is not connected to the non-resist forming section 43, which is at the bottom of the notch filter 70, and the inside relay opening 50. However, the sealing resin 6 is supplied to the non-resist forming section 45 from the outside of the substrate surface 8 through the outside relay opening 52, and the chip component 90 can be completely sealed using the resin. Therefore, it is possible to avoid the voids at that location.

Further, factors, such as the lands 19, the surface wiring pattern 24 and the solder resist layer 30, which are formed depending on the arrangement of the small-sized chip components 90 and which impedes the fluidity of the resin are removed between the non-resist forming section 42 at the bottom of the large-sized IC 60 and the non-resist forming sections 43 and 44 at the bottoms of the middle-sized notch filter 70 and the crystal oscillator 80, and only the relay openings 48 and 49 which expose the substrate surface 8 are present likewise. Therefore, even though the plurality of electronic components which have various types of sizes are mounted on the substrate surface 8, it is possible to easily fill the bottom of each of the component rear surfaces with the resin.

Further, in addition, since a large amount of sealing resin 6 flows from the inlet side resin inlet 41, which is continuous to the front side 11 and is formed in a large scale, toward the non-resist forming region 40, the fluidity of the resin further increases.

Further, after the resin rapidly fills into the non-resist forming region 40, the resin is derived from the resin outlet 54 which is continuous to the rear side 14. Therefore, if a plurality of insulating substrates 4 are coupled and assembled in the process of manufacturing the tuner 2, the resin which is derived from the resin outlet 54 can be flowed from the resin inlet 41 of another adjacent insulating substrate 4, and thus it is possible to improve the efficiency of the sealing operation of the resin.

Further, in addition, when viewed from the substrate surfaces 8 which are positioned front and back, the resin outlet 54 faces the resin inlet 41. Therefore, compared to a case in which the resin inlet 41 and the resin outlet 54 are provided on a side in which the substrate surfaces 8 cross each other and do not face each other, it is possible to arrange a further wider non-resist forming region 40 in the substrate surface 8, and thus it is possible to maximize the fluidity of the resin.

In addition, the bottom of the component rear surface of the large-sized IC 60 is present throughout the wide range of the substrate surface 8, and a load to the resin operates throughout the wide range. However, if a section which includes the short side 65 of the large-sized IC 60 is close to the resin inlet 41 which is formed in a large scale, the sealing resin 6 easily flows toward the non-resist forming section 42 under the large-sized IC 60.

Further, if a section which includes the short side 85 of the middle-sized crystal oscillator 80 is close to the resin outlet 54, it is possible to certainly reduce resin-flow resistance, compared to a case in which the resin supposedly flows from the non-resist forming section 44 under the middle-sized crystal oscillator 80 toward the non-resist forming section 42 under the large-sized IC 60.

Further, in addition, if wide gaps 56 are compared with each other and if the IC 60, which can maximize, the wide gaps 56 is close to the resin inlet 41 which is formed in a large scale according to the embodiment, the resin further easily flows toward the non-resist forming sections 42 under the IC 60.

Besides, if the low crystal oscillator 80 having a low wide gap 56 is close to the resin outlet 54, it is possible to certainly reduce resin-flow resistance, compared to the case in which the resin supposedly flows from the non-resist forming section 44 at the bottom of the middle-sized crystal oscillator 80 toward the non-resist forming section 42 at the bottom of the large-sized IC 60.

In addition, the reserve solder 102, which has a height of approximately 30 μm and is formed on the land 16, has a drum shape in conjunction with the solder bump 100 when the IC 60 is mounted on the substrate surface 8 using the reflow, thereby increasing the height of the wide gap 56.

That is, if it is assumed that the height of narrow gap 36 is, for example, approximately 50 μm, the height of the wide gap 56, which is secured using only the solder bump 100 without providing the reserve solder 102, is approximately 70 μm since the height of the wide gap 56 corresponds to the non-resist forming region 40 from which a solder resist layer 30 having a height of approximately 20 μm is removed. In contrast, the wide gap 56 which is secured by providing the reserve solder 102 is approximately 100 μm. Therefore, it is possible to significantly reduce the resin-flow resistance.

Further, like the inner wiring pattern 26, if the wiring pattern is attempted to be layered internally, it is possible to omit the solder resist layer 30 for the substrate surface 8. Therefore, the range of the solder resist layer 30 is reduced, and it is possible to install the non-resist forming region 40 between the front side 11 and the rear side 14 in the substrate surface 8 throughout a wide range.

Here, if the non-resist forming region 40 is formed in a wide range and the range of the solder resist layer 30 is reduced, the fluidity of the resin is improved. Besides, the solder resist layer 30 in an extremely small area degrades the function of protecting the surface wiring pattern 24, and, in addition, is hardly subjected to the substrate surface 8.

Here, for example, like the adjacent chip components 90 in a narrow region, when the solder resist layer 30 is interposed between the lands 19, 19 which are close to each other, adjacent solder resist layers 30 are connected and form an approximate U shape. Therefore, it is possible to secure an area which is necessary to secure the function of the solder resist layer 30 and to easily install the solder resist layer 30 while the non-resist forming region 40 is formed in a wide range.

The present invention is not limited to the above-described embodiment, and various modifications can be made without departing from the scope of the claims.

For example, in the above-described embodiment, a plurality of electronic components are mounted on the substrate surface. However, if a range from a side to another side runs through the non-resist forming region of the wide gap, the present invention can be applied to a case in which a single larger-sized electronic component is mounted on the substrate surface.

In addition, in the above-described embodiment, the front side 11 and the rear side 14 are arranged in parallel and the form thereof is optimal. According to the present invention, like the front side 11 and, for example, the right-side lateral side 13, each of the front side 11 and the rear side 14 may be provided on a side in which the resin inlet 41 crosses the resin outlet 54.

Further, in addition, the lands on which the reserve solders are installed are not necessarily limited to only a large-sized electronic component. The reserve solders may be installed on lands which are connected to a middle-sized or small-sized electronic component and the wide gap thereof may be further higher.

Further, in addition, the above-described embodiment has been described as an example which is implemented as the television tuner 2. However, if the molded underfill structure is used, the present invention can be deservedly applied to various types of electronic component modules, such as a communication module for short-distance wireless communication.

Further, in every case, like the above, there is an advantage in that it is possible to improve connection reliability while the advantage of the molded underfill structure is maintained.

It should be understood by those skilled in the art that various modifications, combinations, sub-combinations and alterations may occur depending on design requirements and other factors insofar as they are within the scope of the appended claims of the equivalents thereof.

What is claimed is:

1. An electronic component module comprising:
a rectangular insulating substrate;
lands arranged on a substrate surface of the insulating substrate;
electronic components connected to the lands using solder, and mounted on the substrate surface;
a solder resist protective layer that protects a wiring pattern by covering the substrate surface, and that is raised from the substrate surface toward the electronic components;
a non-resist forming region that is not subjected to the solder resist and that exposes the substrate surface; and
a sealing resin that seals the electronic components on the substrate surface,
wherein the non-resist forming region is configured as to communicate one side which partitions the substrate surface with another side which is separated from the one side, which partitions the substrate surface, through bottoms of component rear surfaces of the electronic components on the substrate surface.

2. The electronic component module according to claim 1,
wherein, on the substrate surface, a plurality of electronic components are mounted, and
wherein the non-resist forming region includes non-resist forming sections which are provided at the bottoms of the component rear surfaces of the respective electronic components, and relay openings which communicate with the respective non-resist forming sections.

3. The electronic component module according to claim 2,
wherein the component rear surfaces of the electronic components are formed in rectangular shapes partitioned by long sides and short sides which are cross to each other, and
wherein a long side of a large-sized or middle-sized electronic component of each of the electronic components is arranged along a non-resist forming region formation direction, and a small-sized electronic component is not arranged between the large-sized electronic component and the middle-sized electronic component.

4. The electronic component module according to claim 1,
wherein the non-resist forming region includes an inlet-side substrate edge opening which is continuous to the one side and forms an inlet of the sealing resin, and an outlet-side substrate edge opening which is continuous to the another side and forms the outlet of the sealing resin, and
wherein an area of the inlet-side substrate edge opening is formed to be larger than an area of the outlet-side substrate edge opening.

5. The electronic component module according to claim 4,
wherein the outlet-side substrate edge opening is provided on an opposite side to the inlet-side substrate edge opening while interposing the substrate surface therebetween.

6. The electronic component module according to claim 4,
wherein a section of a largest-sized electronic component of the plurality of electronic components which are mounted on the substrate surface is close to the inlet-side substrate edge opening.

7. The electronic component module according to claim 4,
wherein an electronic component, which has a highest gap from a component rear surface to the substrate surface, of the plurality of electronic components which are mounted on the substrate surface is caused to be close to the inlet-side substrate edge opening, and an electronic component which has a lowest gap is caused to be close to the outlet-side substrate edge opening.

8. The electronic component module according to claim 1,
wherein, on each of the lands, when the electronic components are mounted on the substrate surface using reflow, a reserve solder, which is integrated with the solder and which causes a gap from the component rear surfaces to the substrate surface to be higher than a gap which is formed using only the solder, is formed.

9. The electronic component module according to claim 1,
wherein the insulating substrate includes the wiring pattern that is arranged on an inner layer of the insulating substrate and is connected to the lands.

10. The electronic component module according to claim 1,
wherein, in the protective layer, a protective layer which is interposed between close lands is connected to an adjacent protective layer, and forms an approximately U shape which covers a part of the lands.
